(19) United States
(12) Patent Application Publication
(10) Pub. No.: US 2007/0132469 A1
(43) Pub. Date: Jun. 14, 2007

(54) Inspection device and method

(75) Inventor: Tomomi Yano, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/498,169

(22) Filed: Aug. 3, 2006

(30) Foreign Application Priority Data
Dec. 9, 2005 (JP) 2005-356395

(51) Int. Cl. G01R 31/02

(52) U.S. Cl. 324/760

(57) ABSTRACT

A second temperature control mechanism is configured by providing a gas circulator circulating a gas, in this case air, with an expected temperature, a pair of temperature sensors installed on upper and lower side surfaces of a mounted probe card respectively, and a gas temperature controller adjusting and controlling the temperature of the air circulated in the gas circulator.

### CROSS-REFERENCE TO RELATED APPLICATIONS

This application is based upon and claims the benefit of priority from the prior Japanese Patent Application No. 2005-356395, filed on Dec. 9, 2005, the entire contents of which are incorporated herein by reference.

### BACKGROUND OF THE INVENTION

1. Field of the Invention

The present invention relates to an inspection device and method for inspecting, for example, a semiconductor substrate being a body to be inspected while mounting, for example, a probe card being an inspection body.

2. Description of the Related Art

Conventionally, semiconductor inspection devices have been developed in which various electrical inspections for each semiconductor chip are carried out under high temperature or low temperature in the condition that a number of semiconductor chips are formed on a substrate, for example, a semiconductor substrate (a semiconductor wafer), with the early defects rejection and the substrate sales as the object.

A conventional and general semiconductor inspection device is shown in FIG. 3.

The semiconductor inspection device is configured by providing a wafer stage unit 106 on which each one of semiconductor wafers 105, which are the body to be inspected, is placed and fixed; a probe main body 107 within the inside of which the wafer stage unit 106 is accommodated; an inspection mechanism 110 for the semiconductor wafer 105; and a temperature control mechanism cooling and heating the semiconductor wafer 5 with the room temperature as the basis.

On the surface of the semiconductor wafer 105, a plurality of semiconductor chips (not shown) are formed, and by using the semiconductor inspection device, various electrical inspections are carried out in the condition that semiconductor chips are formed in the semiconductor wafer 105 (in the condition of not yet being separated into each semiconductor chip).

Formed is a card mounting unit 112 on the probe main body 107 on which a probe card 104 being the inspection body is mounted. The card mounting unit 112 provides the probe card 104 at a position opposite to the semiconductor wafer 105, when the probe card 104 is mounted thereon.

The probe card 104 is an inspection body being provided with an electric and electronic circuitries for carrying out the electrical inspection corresponding to the semiconductor wafer 105 (each semiconductor chip formed thereon) being the object of the inspection. There are provided many probes 104a (only two are shown in the illustrated example) corresponding to respective semiconductor chips of the semiconductor wafer 105 on the surface of the probe card 104, and when the probe card 104 is mounted on the card mounting unit 112 of the probe main body 107, these probes 104a electrically come in contact with the electrodes (not shown) of each semiconductor chip.

The inspection mechanism 110 is configured by providing a motherboard 102 provided with various kinds of electric and electronic circuitries corresponding to the probe cards 104; and an inspection head 101 carrying out various electrical inspections via the probe card 104 and the motherboard 102. The inspection mechanism 110 is electrically connected to the probe card 104 via a contact ring 103.

The temperature control mechanism is configured by a heating mechanism 111 and a cooling mechanism 113.

The heating mechanism 111 is constituted with a heater or the like, which is provided within the inside of the wafer stage unit 106, and heats the semiconductor wafer 105 from the wafer stage unit 106.

The cooling mechanism 113 is provided for the probe main body 107, and cools the semiconductor wafer 105 by cooling the atmosphere inside the probe main body 107.

When carrying out various electrical inspections for the semiconductor wafer 105, in order to be adapted to the operating environment of the semiconductor chip, not only room temperature (degree of 20° C. to 25° C.) but also low temperature (for example, degree of −30° C.) and high temperature environment (for example, degree of 85° C. to 95° C.) are created and the electrical inspection is carried out under the respective environments concerned. In order to create such temperature environment in this semiconductor inspection device, the atmosphere in the probe main body 107 is cooled with the cooling mechanism 113 to obtain a low temperature, and the semiconductor wafer 105 is heated from the wafer stage unit 106 with the heating mechanism 111 to obtain a high temperatures.

However, in the case that the application of the low temperature or high temperature to the semiconductor wafer is performed as described above in the condition that the probe card 104 is mounted on the card mounting unit 112 of the probe main body 107, the following problems take place.

The lower surface side (the probe 104a side) of the probe card 104 results in a temperature approximately close to the applied temperatures, because, in the case of applying the high temperature with the heating mechanism 111, heat is transferred through the probe 104a being in contact with the semiconductor wafer 105, and in the case of applying low temperature, it is under the low temperature atmosphere. On the other hand, because the upper surface side of the probe card 104 is in contact with the room temperature atmosphere, the room temperature is substantially maintained on the upper side of the probe card 104.

In this way, there is the problem that the temperature difference arises between the upper surface and the lower surface of the probe card 104, so that warping occurs in the probe card 104 caused by this temperature difference. The measurement failures occur caused by the contact abnormalities of the probe 104a at the time of the electrical inspection for the semiconductor wafer 105, and the external appearance failures occur caused by the abnormal needle mark because of the warping in the probe card 104.

As one technique for reducing this problem, Patent Document 1 (Japanese Patent Application Laid-Open No. Hei 11-51972) discloses a technique in which a metal reinforcing plate is attached to the probe card to prevent it from warping. However, in order to suppress the warping in the probe card with the diameter increased, it is necessary to change the quality of material of the reinforcing plate, or enlarge the reinforcing plate. In this case, there are problems that the weight of the probe card increases, handling is not easy, and the price of the probe card is increased caused by the cost increase of the reinforcing-plate component, and the like. Moreover, Patent Document 2 (Japanese Patent Application Laid-Open No. 2000-138268) discloses one technique in which a heater is provided on the upper surface side of the probe card to heat. However, in this case there is the problem that applying high temperatures can be handled but applying low temperatures can not be handled.

### SUMMARY OF THE INVENTION

The present invention has been achieved in consideration of the above-mentioned problems, and an object of the present invention is to provide a semiconductor inspection device and a method wherein when applying low temperature and high temperature to the semiconductor substrate with the room temperature as the basis, the temperature of the inspection body is uniformly adjusted, easily, quickly, and certainly, so that the occurrence of a warping in the inspection body resulting from a local temperature difference of the inspection body is prevented, thereby realizing highly reliable electrical inspections for semiconductor substrates, and resulting in remarkable contribution to reduction in weight of the inspection body, and to the cost reduction of component expenses.

A semiconductor inspection device of the present invention comprises a body to be inspected installation unit on which the body to be inspected is installed, an inspection body mounting unit on which an inspection body is mounted that carries out electrical inspections corresponding to the body to be inspected; an electrical inspection unit that carries out the electrical inspection for the body to be inspected using the mounted inspection body; and a temperature controller that adjusts and controls the inspection body as a whole under a uniform temperature by circulating a gas with an expected temperature to at least a part of the inspection body.

A semiconductor inspection method according to the present invention adjusts to control the inspection body as a whole in the uniform temperature by circulating a gas with an expected temperature to come into contact with at least a part of the inspection body, when carrying out the electrical inspection for the body to be inspected using the inspection body under the condition that the body to be inspected is installed and the inspection body for carrying out electrical inspections corresponding to the body to be inspected is mounted.

### BRIEF DESCRIPTION OF THE DRAWINGS

FIG. 1 is a schematic view showing a rough configuration of a semiconductor inspection device according to the present embodiment;

FIG. 2 is a flow chart showing a semiconductor inspection method in the sequence of steps according to the present embodiment; and

FIG. 3 is a schematic view showing a rough configuration of a conventional and general semiconductor inspection device.

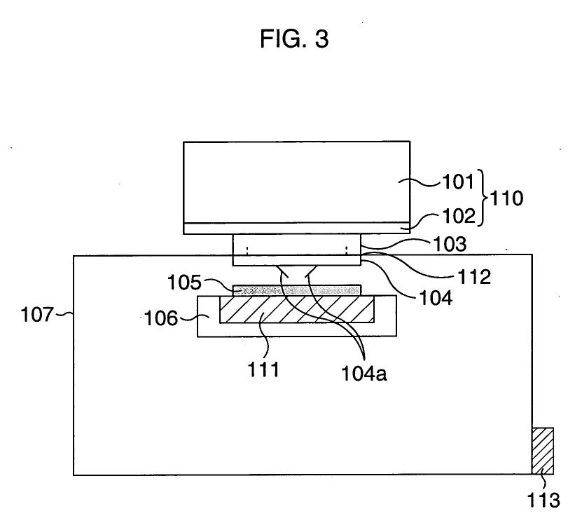

### DETAILED DESCRIPTION OF THE PREFERRED EMBODIMENTS

—Basic Gist of the Present Invention—

The inventor of the present invention, as a technique of cooling and heating at least a part of the probe card with the room temperature as the basis, has found constitution causing a gas with temperature balancing the temperature of a semiconductor wafer to circulate onto the part of the probe card, with relatively simple configuration. It is possible to prevent the probe card from the warping resulting from the temperature difference while adjusting the temperature of the probe card easily and quickly upon using gas, for example, air, as the cooling and/or heating medium for the probe card.

Here, as the specific configuration for circulating gas, there is adopted configuration in which provided is a gas blower having a cavity portion located on the upper surface of the mounted probe card in order to blow the gas with the expected temperature into the cavity. Furthermore, it causes the probe card as a whole to adjust and control at a uniform temperature by providing the respective temperature sensors on the lower surface and the upper surface of the probe card, while sensing each temperature of the lower surface and the upper surface.

Furthermore, in the inspection device according to the present invention, there is specified the allowable range of local temperature difference produced in the probe card with respect to the temperature sensors, and the electrical inspection is interrupted when the local temperature difference in the probe card deviates from the above allowable range on the occasion of the electrical inspection. Then, when the temperature difference falls in the allowable range by circulating a gas as described above, the electrical inspection is restarted. By using the inspection device with such configuration, it becomes possible to certainly carry out an automatic electrical inspection corresponding to the various temperatures that are adapted to the operating environment of the semiconductor chip with minimum time.

—Specific Embodiment to which the Present Invention is Applied—

There will be described a specific embodiment in detail where the present invention is applied to the semiconductor inspection device while referring to the accompanying drawings below.

[Configuration of Semiconductor Inspection Device]

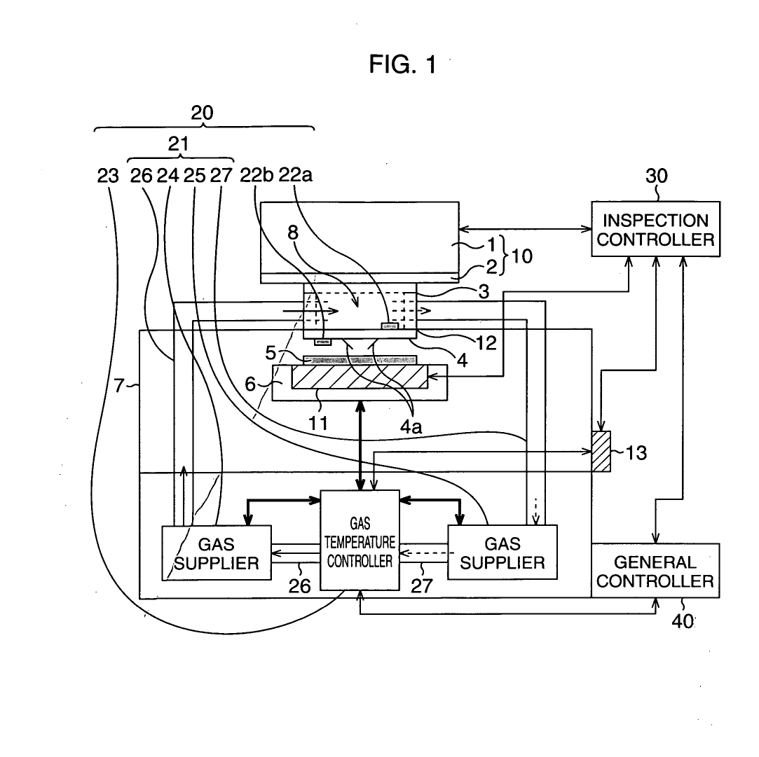

FIG. 1 is a schematic view showing a rough configuration of a semiconductor inspection device according to the present embodiment.

This semiconductor inspection device is configured by comprising a wafer stage unit 6 on which a semiconductor wafer 5 being the body to be inspected is mounted and fixed; a probe main body 7 within the inside of which the wafer stage unit 6 is accommodated; an inspection mechanism 10 for the semiconductor wafer 5; a first temperature control mechanism that cools and heats the semiconductor wafer 5 with the room temperature of the semiconductor wafer 5 as the basis; a second temperature control mechanism 20 that adjusts and controls the probe card 4 by circulating a gas with an expected temperature; an inspection controller 30 that controls interruption and restart of the electrical inspection depending on the temperature control of the semiconductor wafer 5; and a general controller 40 that overall-controls the driving of the whole device.

A plurality of semiconductor chips (not shown) are formed on the surface of the semiconductor wafer 5, and by using this semiconductor inspection device, various electrical inspections are carried out in the condition that the semiconductor chips are formed in the semiconductor wafer 5 (in the state of not yet being separated into each semiconductor chip).

In the probe main body 7, there is formed a card mounting unit 12 on which a probe card 4, which is the inspection body, is mounted. The card mounting unit 12, when the probe card 4 is mounted, provides the probe card 4 at the position opposite to the semiconductor wafer 5.

The probe card 4 is an inspection body being provided with an electric and electronic circuitries for carrying out the electrical inspection corresponding to the semiconductor wafer 5 (each semiconductor chip formed thereon) being the object of the inspection. There are provided many probes 4a (only two are shown in the illustrated example) corresponding to the respective semiconductor chips of the semiconductor wafer 5 on the surface of the probe card 4, and when the probe card 4 is mounted on the card mounting unit 12 of the probe main body 7, these probes 4a electrically come in contact with the electrodes (not shown) of each semiconductor chip.

The inspection mechanism 10 is configured by comprising a motherboard 2 provided with various kinds of electric and electronic circuitries corresponding to the probe cards 4; and an inspection head 1 carrying out various electrical inspections via the probe card 4 and the motherboard 2. The inspection mechanism 10 is electrically connected to the probe card 4 via a contact ring 3.

The contact ring 3 has a gas blower 8 being a component in the inside thereof, in which a cavity unit is located on the upper surface of the mounted probe card 4. This gas blower 8 is one component of a gas circulator 21 described later.

The first temperature control mechanism is composed of a heating mechanism 11 and a cooling mechanism 13.

The heating mechanism 11 being a heater or the like, is provided within the inside of the wafer stage unit 6, and heats the semiconductor wafer 5 from the wafer stage unit 6.

The cooling mechanism 13 is provided at the probe main body 7, and cools the semiconductor wafer 5 by cooling the atmosphere inside the probe main body 7.

The second temperature control mechanism 20 adjusts the temperature of the probe card 4 easily and quickly upon using gas, for example, air, as the cooling and/or heating medium for the probe card 4.

The second temperature control mechanism 20 is configured by comprising a gas circulator 21 for circulating gas (air in this case) with an expected temperature; a pair of temperature sensors 22a and 22b installed on the upper and lower surfaces of the mounted probe card 4 respectively; and a gas temperature controller 23 for adjusting and controlling the temperature of the air circulated in the gas circulator 21.

The gas circulator 21 is configured by comprising a gas supplier 24 for supplying air; a gas suction unit 25 for sucking air; the gas blower 8 provided in the contact ring 3; a gas supply side pipeline 26 which connects the gas supplier 24 to the gas temperature controller 23 and the gas supplier 24 to gas blower 8, and which constitutes the passage for the air supplied to the gas blower 8; and a gas suction side pipeline 27 which connects the gas suction unit 25 to the gas temperature controller 23 and the gas suction unit 25 to the gas blower 8, and which constitutes the passage for the air sucked in from the gas blower 8.

The temperature sensors 22a and 22b measure each temperature at portions where the temperature difference arises in the probe card 4 (here, in the upper surface and the lower surface thereof), and these are provided so as to come into contact with the upper surface and the lower surface of the mounted probe card 4.

The gas temperature controller 23 is a controller adjusting and controlling the temperature of the air blowing in the gas blower 8 under a relationship between the preset temperature of the semiconductor wafer 5 in accordance with the heating mechanism 11 or the cooling mechanism 13, and the temperatures measured by the pair of temperature sensors 22a and 22b. The gas temperature controller 23 controls the adjustment temperature of the air depending on the preset temperature and the measured temperature, so that the probe card 4 as a whole becomes at a uniform temperature. In addition, for convenience of illustration, in FIG. 1, the situation in which the gas temperature controller 23 is connected to the temperature sensors 22a and 22b will be omitted.

The gas temperature controller 23 is connected to the gas supplier 24 and the gas suction unit 25 via a part of the gas supply side pipeline 26 and a part of the gas suction side pipeline 27, thereby integrally constituting an air circulatory system with the gas blower 8, the gas supplier 24, and the gas suction unit 25. In the illustrated example, the air supply path is shown by the solid line arrow, and the air suction path is shown by the broken line arrow, respectively.

The inspection controller 30 is connected to a pair of temperature sensors 22 and the general controller 40, and has the function of interrupting the electrical inspection if the temperature difference between the temperature sensors 22a and 22b becomes not less than the specified allowable range, for example, becomes not less than degree of 5° C. at the time of the electrical inspection for the semiconductor wafer 5. Then, the inspection controller 30 has the function of restarting the electrical inspection when the temperature difference becomes a value within the specified range by driving the gas temperature controller 23.

The general controller 40 is a controller overall-controlling the inspection operation of the device concerned, and is connected to the inspection mechanism 10, the first temperature control mechanism, the second temperature control mechanism 20, and the inspection controller 30. The general controller 40 appropriately carries out the electrical inspection for the semiconductor wafer 5 using the inspection mechanism 10; the temperature control of the semiconductor wafer 5 using the heating mechanism 11 and the cooling mechanism 13 in the first temperature control mechanism; the operation control of the gas temperature controller 23 in the second temperature control mechanism 20; and instructions of the inspection interruption/restart or the like to the inspection mechanism 10 in response to a inspection interruption signal/inspection restart signal from the inspection controller 30.

[Semiconductor Inspection Method]

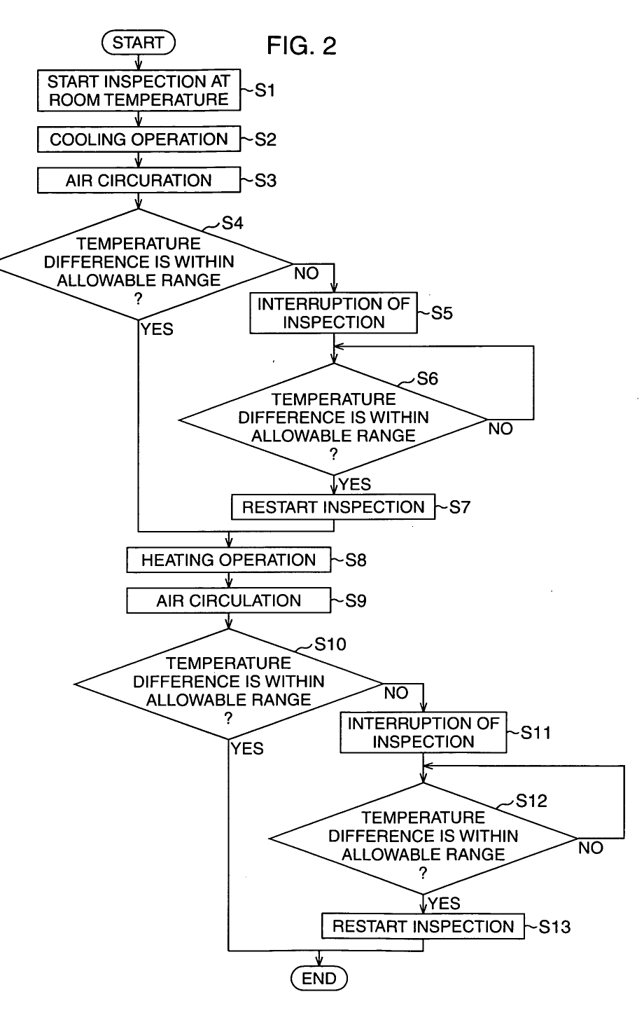

FIG. 2 is a flow chart showing a semiconductor inspection method in the sequence of steps according to the present embodiment.

First, the semiconductor wafer 5 is installed on the wafer stage unit 6, and the general controller 40 drives the inspection mechanism 10 to start the electrical inspection for the semiconductor wafer 5 (each semiconductor chip formed thereon) from at room temperature (approximately, 20° C.-25° C.) with the condition that the card mounting unit 12 of the corresponding probe main body 7 is mounted (Step S1).

Subsequently, after completing the electrical inspection at room temperature (the room temperature inspection), the electrical inspection for the semiconductor wafer 5 at low temperature or at high temperature (the low temperature inspection or high temperature inspection), and the low temperature inspection in this case, is carried out.

Specifically, in order to set the expected low temperature condition (for example, degree of −30° C.) with the room temperature as the basis, the general controller 40 drives the cooling mechanism 13 of the first temperature control mechanism to cool the atmosphere inside the probe main body 7 at the expected preset temperature (Step S2).

Here, the temperature of the lower surface of the probe card 4 decreases depending on the cooling process in Step S2. The present embodiment equalizes the temperature of the probe card 4 as a whole. That is, the second temperature control mechanism 20 circulates the air with the expected temperature within the inside of the gas blower 8 including the upper surface of the probe card 4 in order to eliminate the temperature difference, which is measured with the temperature sensors 22a and 22b, between the upper and lower surfaces of the probe card 4 (Step S3).

Here, the gas temperature controller 23 of the second temperature control mechanism 20 continuously judges whether the temperature difference measured with the temperature sensors 22a and 22b is a value within the allowable range (Step S4). The gas temperature controller 23, when the temperature difference deviates from the allowable range, sends a signal (an inspection interruption signal) indicative of interrupting the electrical inspection to the general controller 40. The general controller 40 having received the inspection interruption signal causes the inspection operation conducted by the inspection mechanism 10 to temporarily interrupt (Step S5).

Following Step S5, the gas temperature controller 23 continues to judge whether the temperature difference is a value within the allowable range (Step S6), and when the temperature difference deviating from the allowable range is settled within the allowable range due to the temperature control of circulating the air inside the gas blower 8, the gas temperature controller 23 sends the signal (the inspection restart signal) indicative of restarting the electrical inspection to the general controller 40. The general controller 40 having received the inspection interruption signal restarts the inspection operation conducted by the inspection mechanism 10 (Step S7).

Subsequently, after completing the low temperature inspection with the temperature difference not deviating from the allowable range in Step S4, or after completing the low temperature inspection while carrying out the inspection interruption/restart in Steps S5 and S7, the high temperature inspection is carried out consecutively.

Specifically, the general controller 40 heats, from the wafer stage unit 6, the semiconductor wafer 5 to the expected preset temperature while driving the heating mechanism 13 of the first temperature control mechanism in order to set to the expected high temperature condition (for example, degree of 85° C. to 95° C.) with the room temperature as the basis (Step S8).

Here, the temperature of the lower surface of the probe card 4 increases depending on the heating treatment in Step S8. The present embodiment equalizes the temperature of the whole probe card 4. That is, the second temperature control mechanism 20 circulates the air with the expected temperature within the inside of the gas blower 8 including the upper surface of the probe card 4 in order to eliminate the temperature difference between the upper and the lower surfaces of the probe card 4 measured by the temperature sensors 22a and 22b (Step S9).

Here, the gas temperature controller 23 in the second temperature control mechanism 20 continuously judges whether the temperature difference measured by the temperature sensors 22a and 22b is a value within the allowable range (Step S10). In the case that the temperature difference deviates from the allowable range, the gas temperature controller 23 sends the signal (the inspection interruption signal) indicative of interrupting the electrical inspection to the general controller 40. The general controller 40 having received the inspection interruption signal interrupts temporarily the inspection operation conducted by the inspection mechanism 10 (Step S11).

Following Step S11, the gas temperature controller 23 continues to judge whether the temperature difference is a value within the allowable range (Step S12), and when the temperature difference, which deviates from the allowable range, has been settled within the allowable range depending on the temperature control of circulating the air into the gas blower 8, the gas temperature controller 23 sends the signal (the inspection restart signal) indicative of restarting the electrical inspection to the general controller 40. The general controller 40 having received the inspection restart signal restarts the inspection operation conducted by the inspection mechanism 10 (Step S13).

Then, after completing the high temperature inspection with the temperature difference not deviating from the allowable range in Step S10, or after completing the high temperature inspection while carrying out the inspection interruption/restart in Steps S11 and S13, the general controller 40 stops the driving of the inspection mechanism 10 to complete the electrical inspection for the semiconductor wafer 5.

In addition, in the semiconductor inspection method described above, although there is exemplified the case in which the electrical inspection is carried out in sequence of the room temperature inspection, the low temperature inspection, and the high temperature inspection, these also can be carried out at random, and moreover, not to mention, only one or two of these inspections can be carried out.

As described above, according to the present embodiment, when applying the low temperature and the high temperature with the room temperature as the basis to the semiconductor wafer 5, the temperature of the probe card 4 is uniformly adjusted easily, quickly, and certainly, there is prevented from occurring of a warping in the probe card 4 resulting from the temperature difference between the upper and lower surfaces of the probe card 4, thereby realizing a highly reliable electrical inspection for the semiconductor wafer 5, and enabling a remarkable contribution to reduction in weight of the probe card 4, and the cost reduction of component expenses.

According to the present invention, when applying low temperature and high temperature to the semiconductor substrate with the room temperature as the basis, the temperature of the inspection body is uniformly adjusted, easily, quickly, and certainly, so that the occurrence of deformation of the inspection body (a warping for the case of probe card) resulting from a local temperature difference of the inspection body is prevented, thereby realizing highly reliable electrical inspections for semiconductor substrates, and resulting in remarkable contribution to reduction in weight of the inspection body, and to the cost reduction of component expenses.

What is claimed is:

1. An inspection device comprising:
a body to be inspected installation unit on which the body to be inspected is installed;
an inspection body mounting unit on which the inspection body is mounted that carries out an electrical inspection corresponding to the body to be inspected;
the electrical inspection unit that carries out the electrical inspection for the body to be inspected using the mounted inspection body; and
a temperature controller that adjusts and controls the inspection body as a whole in a uniform temperature by circulating a gas with an expected temperature onto at least a part of the inspection body.

2. The inspection device according to claim 1, further comprising a temperature setting mechanism that adjusts the body to be inspected to an expected preset temperature at a time of the electrical inspection, wherein the temperature controller adjusts and controls the temperature of the gas corresponding to the preset temperature so that the inspection body as a whole is at a uniform temperature.

3. The inspection device according to claim 2, wherein the temperature setting mechanism is configured by comprising a heating unit heating the body to be inspected from the body to be inspected installation unit; and a cooling unit cooling the atmosphere around the body to be inspected.

4. The inspection device according to claim 1, further comprising a gas blower having a cavity located on the upper surface of the inspection body, wherein the temperature controller blows a gas into the cavity of the gas blower.

5. The inspection device according to claim 1, further comprising a temperature measurement unit installed in a plurality of locations of the body to be inspected.

6. The inspection device according to claim 1, wherein the temperature controller specifies the allowable range of local temperature difference produced in the inspection body, and the inspection device further comprising an inspection interruption unit having a function of interrupting the electrical inspection when the local temperature difference produced in the inspection body deviates from the allowable range at the time of the electrical inspection.

7. The inspection device according to claim 6, wherein the inspection interruption unit has a function of restarting the electrical inspection when the temperature difference falls within the allowable range after the interruption.

8. The inspection device according to claim 1, wherein the body to be inspected is a semiconductor substrate on a surface of which a plurality of semiconductor chips are formed.

9. The inspection device according to claim 8, wherein the inspection body is a plate-like one provided with a plurality of probes corresponding to the respective semiconductor chips.

10. An inspection method, wherein when carrying out an electrical inspection for a body to be inspected using an inspection body in a condition where the body to be inspected is installed and the inspection body carrying out the electrical inspection corresponding to the body to be inspected is mounted, the inspection body as a whole is made to adjust and control at a uniform temperature while circulating a gas with an expected temperature onto at least a part of the inspection body.

11. The inspection method according to claim 10, wherein the inspection method adjusts and controls the temperature of the gas corresponding to the preset temperature so that the inspection body as a whole arrives at a uniform temperature at the time of the electrical inspection upon adjusting the body to be inspected to an expected preset temperature.

12. The inspection method according to claim 10, wherein the gas is blown into the cavity provided on the upper surface of the inspection body.

13. The inspection method according to claim 10, wherein there is specified an allowable range of a local temperature difference produced in the inspection body, and the electrical inspection is interrupted when the local temperature difference produced in the inspection body deviates from the allowable range at a time of the electrical inspection.

14. The inspection method according to claim 13, wherein the electrical inspection is restarted when the temperature difference falls within the allowable range after the interruption.

15. The inspection method according to claim 10, wherein the body to be inspected is a semiconductor substrate on the surface of which a plurality of semiconductor chips are formed.

16. The inspection method according to claim 15, wherein the inspection body is a plate-like one provided with a plurality of probes corresponding to the respective semiconductor chips.
